(19) United States
(12) Patent Application Publication
(10) Pub. No.: US 2026/0190527 A1
(43) Pub. Date: Jul. 2, 2026

(54) METHOD FOR MANUFACTURING SEMICONDUCTOR DEVICE

(71) Applicant: CANON KABUSHIKI KAISHA, Tokyo (JP)

(72) Inventors: KOJI HARA, Chiba (JP); AKIRA MATSUZAKI, Kanagawa (JP); ATSUSHI FURUBAYASHI, Kanagawa (JP)

(21) Appl. No.: 19/424,984

(22) Filed: Dec. 18, 2025

(30) Foreign Application Priority Data
Dec. 26, 2024 (JP) 2024-230270

(51) Int. Cl. H10F 39/00

(52) U.S. Cl. CPC H10F 39/8063; H10F 39/8053

(57) ABSTRACT

A method for manufacturing a semiconductor device including a substrate, the substrate including a first surface, a second surface opposed to the first surface, and a plurality of semiconductor regions disposed between the first and second surfaces. The method includes preparing the substrate to include a separation portion having a trench structure extending from the first surface and a member disposed inside the trench structure, the separation portion separating the plurality of semiconductor regions, and forming a first film including a flat upper surface by applying a precursor onto the substrate so that an amount of the precursor applied to an upper portion of the separation portion is different from an amount of the precursor applied to a portion other than the upper portion of the separation portion.

### BACKGROUND

### Field of the Technology

The present disclosure relates to a method for manufacturing a semiconductor device.

### Description of the Related Art

Japanese Patent Laid-Open No. 2017-199875 describes a semiconductor device including a separation portion extending from a light incident surface side of a semiconductor substrate.

In a step of manufacturing the semiconductor device including the separation portion described in Japanese Patent Laid-Open No. 2017-199875, there is a case where the flatness of an insulating film after the separation portion is formed becomes low.

### SUMMARY

According to an aspect of the present disclosure, a method for manufacturing a semiconductor device including a substrate, the substrate including a first surface, a second surface opposed to the first surface, and a plurality of semiconductor regions disposed between the first and second surfaces. The method includes preparing the substrate to include a separation portion having a trench structure extending from the first surface and a member disposed inside the trench structure, the separation portion separating the plurality of semiconductor regions, and forming a first film including a flat upper surface by applying a precursor onto the substrate so that an amount of the precursor applied to an upper portion of the separation portion is different from an amount of the precursor applied to a portion other than the upper portion of the separation portion.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic diagram illustrating a configuration of a planarization apparatus.

FIGS. 2A, 2B, and 2C are schematic diagrams illustrating a planarization process.

FIGS. 3A and 3B are schematic diagrams illustrating a method for manufacturing a semiconductor device according to a first embodiment.

FIGS. 4A, 4B, 4C, and 4D are schematic diagrams illustrating a method for manufacturing a semiconductor device according to the first embodiment.

FIG. 5 is a schematic diagram illustrating a configuration of the semiconductor device according to the first embodiment.

FIGS. 6A and 6B are schematic diagrams illustrating a method for manufacturing a semiconductor device according to the first embodiment.

FIGS. 7A, 7B, 7C, and 7D are schematic diagrams illustrating a method for manufacturing a semiconductor device according to a second embodiment.

FIGS. 8A, 8B, 8C, and 8D are schematic diagrams illustrating a method for manufacturing a semiconductor device according to the second embodiment.

FIG. 9 is a schematic diagram illustrating a configuration of the semiconductor device according to the second embodiment.

FIGS. 10A, 10B, 10C, and 10D are schematic diagrams illustrating a method for manufacturing a semiconductor device according to a third embodiment.

FIGS. 11A, 11B, 11C, and 11D are schematic diagrams illustrating a method for manufacturing a semiconductor device according to a fourth embodiment.

FIGS. 12A, 12B, 12C, and 12D are schematic diagrams illustrating a method for manufacturing a semiconductor device according to a fifth embodiment.

FIGS. 13A, 13B, and 13C are schematic diagrams illustrating application examples of a semiconductor device according to a sixth embodiment.

### DESCRIPTION OF THE EMBODIMENTS

Embodiments will be described below with reference to the drawings. The following embodiments do not limit the disclosure according to the appended claims. Although a plurality of features is described in the embodiments, not all the plurality of features is essential for the disclosure, and the plurality of features may be optionally combined together. Further, in the attached drawings, the same or similar components are designated by the same reference numbers, and are not occasionally redundantly described.

Embodiments of the present disclosure will be described in detail below based on the drawings. In the following description, terms indicating particular directions and positions (e.g., “up”, “down”, “right”, and “left” and other terms including these terms) are used where necessary. These terms are used to facilitate the understanding of the embodiments with reference to the drawings, and the meanings of the terms do not limit the technical scope of the present disclosure.

In the specification, a “planar view” refers to a view from a direction perpendicular to an upper surface of a semiconductor substrate. A “cross-sectional view” refers to a surface in a direction perpendicular to the upper surface of the semiconductor substrate. In a case where the upper surface of the semiconductor substrate is a rough surface when viewed microscopically, a planar view is defined based on the upper surface of the semiconductor substrate when viewed macroscopically. The upper surface of the semiconductor substrate is a surface on which an element formed on the semiconductor substrate, such as the gate of a transistor, is provided, or a surface including a connection portion with a contact plug.

The expressions “A or B”, “at least one of A and B”, “at least one of A and/or B”, “one or more of A and/or B”, and the like include all the possible combinations of the listed items, unless explicitly defined. That is, it is understood that the above expressions disclose all of a case where at least one A is included, a case where at least one B is included, and a case where both at least one A and at least one B are included. This is also similarly applied to the combinations of three or more elements.

### First Embodiment

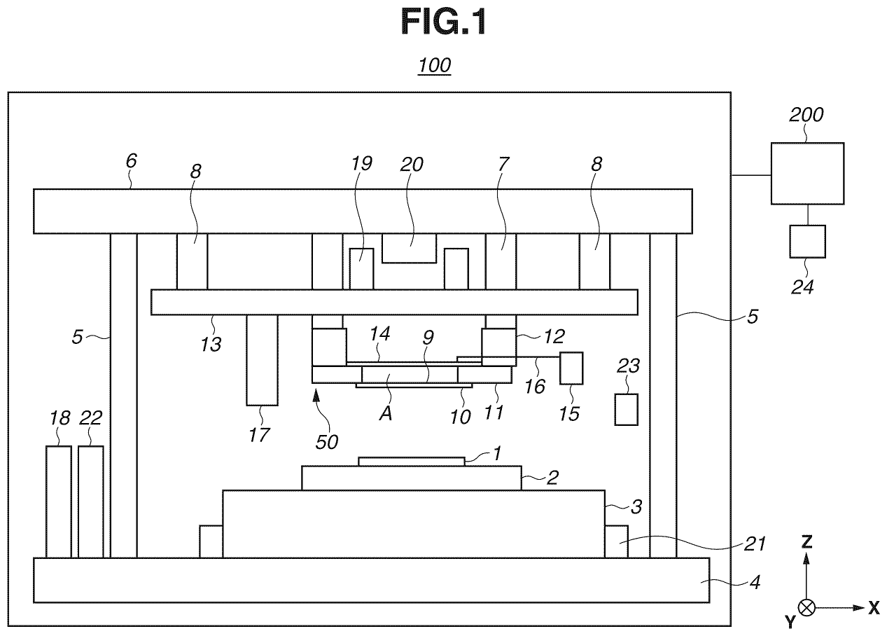

FIG. 1 is a schematic diagram illustrating the configuration of a planarization apparatus 100 according to a first embodiment. Directions are represented in an XYZ coordinate system where a horizontal plane is an XY plane. Generally, a substrate 1 as a processing target object is placed on a substrate stage 3 so that the surface of the substrate 1 is parallel to the horizontal plane (the XY plane). In the following description, directions orthogonal to each other in a plane along the surface of the substrate 1 are an X-axis and a Y-axis, and a direction perpendicular to the X-axis and the Y-axis is a Z-axis. In the following description, directions parallel to the X-axis, the Y-axis, and the Z-axis in the XYZ coordinate system are referred to as an “X-direction”, a “Y-direction”, and a “Z-direction”, respectively, and a rotational direction about the X-axis, a rotational direction about the Y-axis, and a rotational direction about the Z-axis are referred to as a “θX-direction”, a “θY-direction”, and a “θZ-direction”, respectively. Although described below, the substrate 1 is a member to which a semiconductor process is applicable, such as a semiconductor wafer, a semiconductor wafer on which a wiring structure is formed, a glass substrate on which an element is formed, a metal substrate, or the like.

A base pattern on a substrate has an uneven profile caused by a pattern formed in a previous step. Particularly, with the multilayered structurization of a memory element in recent years, some process substrates may have a difference in level of about 100 nm. A difference in level caused by the gentle undulation of the entirety of a substrate can be corrected by a focus tracking function of a scanning exposure apparatus used in a photolithography step. However, unevenness at fine pitches that fall within the area of an exposure slit of the exposure apparatus may be outside the depth of focus (DOF) of the exposure apparatus. Conventionally, as a technique for smoothing a base pattern on a substrate, a technique for forming or planarizing a planarization layer, such as spin-on carbon (SOC) or chemical mechanical polishing (CMP), is used. In the conventional art, however, sufficient planarization performance cannot be obtained. For example, a manufacturing process evolves into a new technology node such as 22 nm, 16 nm, 14 nm, or 10 nm. Even if a planarization layer sufficient for practical use in a node of a generation ago is obtained, there is a case where the planarization layer cannot withstand practical use in a subsequent node. Examples of this case include a case where the unevenness of the surface of the planarization layer tolerated in the previous node is not tolerated in the subsequent node. While the process cost of CMP is expensive and applicable steps are limited, the difference in unevenness in a base due to multilayering tends to further increase in the future.

To solve this issue, a planarization apparatus that planarizes a substrate using an imprint technique is considered. The planarization apparatus brings a flat surface of a member or a member on which a pattern is not formed (a planar template) into contact with a composition in an uncured state supplied in advance to a substrate, thereby planarizing a local part of the surface of the substrate or the entire surface of the substrate. Then, the planarization apparatus cures the composition in the state where the composition and the planar template are in contact with each other, and separates the planar template from the cured composition.

This forms a planarization layer on the substrate. This planarization apparatus is not influenced by the unevenness of a pattern surface of a substrate in a planarization method using a commonly used SOC sacrificial film, and therefore is expected to improve the accuracy of planarization compared to an existing method.

The planarization apparatus 100 in FIG. 1 can be embodied by a molding apparatus that molds a composition on the substrate 1 using a plate (superstrate) 9 as a pressing member. The planarization apparatus 100 cures a composition in the state where a material on the substrate 1 and the plate 9 are in contact with each other, and pulls the plate 9 away from the cured composition, thereby forming a planarization layer of the material on the substrate 1.

The substrate 1 is a semiconductor, an insulator, or a metal substrate. The shape of the substrate 1 can be a circle as in a silicon wafer or a quartz wafer, or a rectangle as in (mother) glass for a flat panel display (FPD). The material of the substrate 1 can be a monocrystalline silicon wafer, but is not limited to this. The material of the substrate 1 can be an elemental semiconductor or a compound semiconductor such as silicon, germanium, diamond, silicon carbide, silicon germanium, gallium nitride, gallium arsenide, indium arsenide, or cadmium telluride. The material of the substrate 1 can be an inorganic insulator such as silicon oxide, silicon nitride, aluminum oxide, or aluminum nitride. The material of the substrate 1 can be an organic insulator such as polyimide, polyamide, or polycarbonate. The substrate 1 may be aluminum, a titanium-tungsten alloy, an aluminum-silicon alloy, or an aluminum-copper-silicon alloy. In sum, the substrate 1 can be composed of one or more materials optionally selected from among the above materials and the like. On the surface of the substrate 1, at least one layer of a semiconductor, an insulator, or a metal film may be formed, and the surface of the layer can be flat, or unevenness can be formed on the surface of the layer.

On the surface of the substrate 1, an adhesion layer may be formed by surface treatment such as silane coupling treatment, silazane treatment, the formation of an organic thin film, or the like, and the substrate 1 having improved adhesiveness with the composition may be used. Typically, the shape of the substrate 1 is a circle having a diameter of 300 mm, but is not limited to this.

The plate 9 can be composed of a material having light transmission properties in consideration of a light irradiation step. For example, this material is an inorganic material having light transmission properties, such as glass, quartz, or the like, or an organic material having light transmission properties, such as polymethyl methacrylate (PMMA), a polycarbonate resin, or the like. The plate 9 may be a plate having rigidity, or may be a flexible film. Then, the surface of the plate 9 that comes into contact with the composition is flat. It is desirable that the shape of the plate 9 be a circle having a diameter greater than 300 mm and smaller than 500 mm. The present disclosure, however, is not limited to this. It is desirable that the thickness of the plate 9 be 0.25 mm or more and less than 2 mm. The present disclosure, however, is not limited to this. In a case where the composition is not a light-curable material but a heat-curable material, the plate 9 does not need to be transparent, and only needs to be composed of a material having the above characteristics.

The composition is a precursor that cures and becomes at least a part of a planarization film, and is a curable composition capable of curing by receiving light or heat energy. The curable composition capable of curing by receiving light or heat energy can be a light-curable composition that cures by being irradiated with light, a heat-curable composition that cures by being heated, or a light/heat-curable composition that cures by receiving light and heat energy. Examples of the light-curable composition include an ultraviolet (UV) curable liquid. As the UV curable liquid, typically, a monomer such as acrylate or methacrylate can be used. The curable composition may also be termed a “moldable material”. In the following description, a moldable material is also referred to simply as a “material”.

As illustrated in FIG. 1, the planarization apparatus 100 includes a substrate chuck 2, a substrate stage 3, a base surface plate 4, supporting columns 5, a top plate 6, guide bars 7, supporting columns 8, a plate chuck 11, a head 12, and an alignment shelf 13. The planarization apparatus 100 further includes a pressure adjustment unit 15, a supply unit 17, a substrate conveyance unit 18, an alignment scope 19, a light source 20, a stage driving unit 21, a plate conveyance unit 22, a cleaning unit 23, an input unit 24, and a control unit 200. The substrate chuck 2 and the substrate stage 3 can be moved while holding the substrate 1. The plate chuck 11 and the head 12 can be moved while holding the plate 9.

The substrate 1 is carried into the planarization apparatus 100 from outside by the substrate conveyance unit 18 that includes a conveyance hand or the like and held by the chuck 2. The substrate stage 3 is supported by the base surface plate 4 and is driven in the X-direction and the Y-direction to position the substrate 1 held by the substrate chuck 2 at a predetermined position. For example, the stage driving unit 21 includes a linear motor, an air cylinder, or the like and drives the substrate stage 3 at least in the X-direction and the Y-direction, but may have the function of driving the substrate stage 3 in two or more axis directions (e.g., six axis directions). The stage driving unit 21 includes a rotation mechanism and can rotationally drive the substrate chuck 2 or the substrate stage 3 in the θZ-direction.

The plate 9 as a pressing member is carried into the planarization apparatus 100 from outside by the plate conveyance unit 22 that includes a conveyance hand or the like and held by the plate chuck 11. For example, the plate 9 has a circular or quadrangular outer shape and has a first surface including a flat surface 10 that comes into contact with a material placed on the substrate 1, and a second surface on the opposite side of the first surface. In the present embodiment, the flat surface 10 has the same size as that of the substrate 1 or a size larger than that of the substrate 1. The plate chuck 11 is supported by the head 12 and can have the function of correcting the position in the θZ-direction (the tilt about the Z-axis) of the plate 9. Each of the plate chuck 11 and the head 12 includes an opening that transmits light (ultraviolet light) emitted through a collimator lens from the light source 20. The plate chuck 11 functions as a holding unit that mechanically holds the plate 9. For example, the plate chuck 11 holds the plate 9 by attracting the second surface of the plate 9 in the state where the second surface faces up. The head 12 mechanically holds the plate chuck 11. The plate chuck 11 and the head 12 constitute a formation unit 50 that performs a formation process for forming a planarization film. The head 12 constitutes a driving mechanism (not illustrated) for positioning the distance between the substrate 1 and the plate 9 when the plate 9 is brought into contact with a material on the substrate 1 and pulled away from the material. The head 12 moves the plate 9 in the Z-direction. For example, the driving mechanism of the head 12 can be composed of an actuator such as a linear motor, an air cylinder, a voice coil motor, or the like. In the plate chuck 11 or the head 12, a load cell for measuring the pressing force (the imprinting force) of the plate 9 to a material on the substrate can be placed. First, a plate deformation mechanism (a plate deformation unit) includes a sealing member 14 that sets a space region A formed by a space existing inside the plate chuck 11 and an internal space surrounded by the plate 9 as a sealed space. The plate deformation mechanism includes the pressure adjustment unit 15 that is installed outside the plate chuck 11 and adjusts the pressure in the space region A. The sealing member 14 is formed of a flat plate member having light transmission properties, such as quartz glass or the like, and a part of the sealing member 14 includes a connection port (not illustrated) for a pipe 16 connected to the pressure adjustment unit 15. The pressure adjustment unit 15 increases the pressure in the space region A, thereby increasing the amount of convex deformation of the plate 9 to the substrate. The pressure adjustment unit 15 decreases the pressure in the space region A and thereby can make the amount of convex deformation of the plate 9 small. On the base surface plate 4, the supporting columns 5 supporting the top plate 6 are placed. The guide bars 7 are suspended by the top plate 6, penetrate the alignment shelf 13, and are fixed to the head 12. The alignment shelf 13 is suspended by the top plate 6 through the supporting columns 8. The guide bars 7 penetrate the alignment shelf 13. On the alignment shelf 13, for example, a height measurement system (not illustrated) for measuring the height (the degree of flatness) of the substrate 1 held by the substrate chuck 2, using an obliquely incident image shift method is placed.

The alignment scope 19 includes an optical system and an imaging system for observing a reference mark provided on the substrate stage 3 and an alignment mark provided on the plate 9. If, however, the alignment mark is not provided on the plate 9, the alignment scope 19 may not be provided. The alignment scope 19 is used in alignment for measuring the relative position between the reference mark provided on the substrate stage 3 and the alignment mark provided on the plate 9 and correcting a positional shift in the relative position.

The supply unit 17 includes a dispenser including a discharge port (a nozzle) that discharges a material in an uncured state to the substrate 1. The supply unit 17 supplies (applies) the material onto the substrate 1. For example, the supply unit 17 can employ a piezo jet method, a micro solenoid method, or the like and supply a small volume, namely about 1 pL (picoliter), of the material onto the substrate 1 that is being subjected to scanning driving by the substrate stage 3. The number of discharge ports in the supply unit 17 is not limited, and may be one (a single nozzle), or may be two or more (e.g., 100 or more). A linear nozzle array having one or more lines may be composed of a plurality of nozzles. Particularly, a dispenser using a method known as an inkjet head can apply a liquid material as minute droplets to the substrate 1 and therefore is suitable. Particularly, a piezo inkjet head including at least one discharge energy generation body of a piezoelectric element with respect to each discharge port can change the volume of droplets to be discharged and therefore is more suitable.

The cleaning unit 23 cleans the plate 9 in the state where the plate 9 is held by the plate chuck 11. In the present embodiment, the cleaning unit 23 pulls the plate 9 away from a cured material on the substrate 1, thereby removing the material attached to the plate 9, particularly the flat surface 10. For example, the cleaning unit 23 may wipe the material attached to the plate 9, or may remove the material attached to the plate 9 using UV irradiation, static elimination, wet cleaning, dry plasma cleaning, or the like.

The control unit 200 is composed of a computer apparatus including a central processing unit (CPU) and a memory and controls the entirety of the planarization apparatus 100. The control unit 200 functions as a processing unit that performs a planarization process by performing overall control of the components of the planarization apparatus 100. The planarization process is a process of bringing the flat surface 10 of the plate 9 into contact with a material on the substrate 1 and causing the flat surface 10 to follow the surface shape of the substrate 1, thereby planarizing the material. Generally, the planarization process is performed in lot units, i.e., on each of a plurality of substrates included in the same lot.

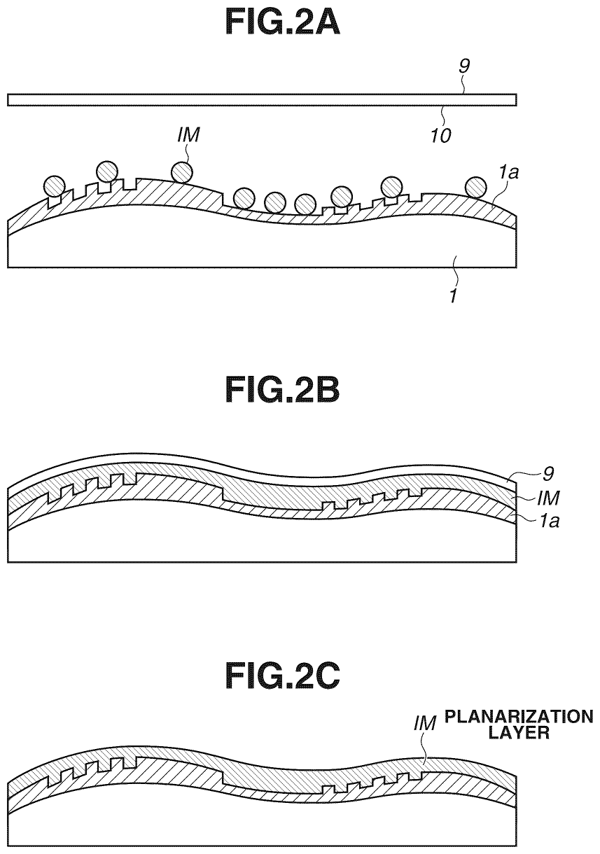

Next, with reference to FIGS. 2A, 2B, and 2C, the planarization process is described. First, the supply unit 17 supplies a material IM to the substrate 1 on which a base pattern 1a is formed. FIG. 2A illustrates the state after the material IM is placed on the substrate 1 and before the plate 9 is brought into contact with the substrate 1. Next, as illustrated in FIG. 2B, the material IM on the substrate 1 and the flat surface 10 of the plate 9 are brought into contact with each other. The plate 9 presses the material IM, whereby the material IM spreads over the entire surface of the substrate 1. FIG. 2B illustrates the state where the entire surface of the flat surface 10 of the plate 9 is in contact with the material IM on the substrate 1, and the flat surface 10 of the plate 9 follows the surface shape of the substrate 1. Then, in the state illustrated in FIG. 2B, the light source 20 irradiates the material IM on the substrate 1 with light through the plate 9. This cures the material IM. Then, the plate 9 is pulled away from the cured material IM on the substrate 1. This forms a layer (a planarization layer) of the material IM having a uniform thickness on the entire surface of the substrate 1. FIG. 2C illustrates the state where the planarization layer of the material IM is formed on the substrate 1. In the following description, the contact (close contact) between the flat surface 10 of the plate 9 and the material IM on the substrate 1 or the separation of the flat surface 10 of the plate 9 and the material IM on the substrate 1 from each other is referred to simply as “the contact (close contact) between the plate 9 and the material IM on the substrate 1” or “the separation of the plate 9 and the material IM on the substrate 1 from each other”. In the following description, the material IM in the state of being supplied to the substrate 1 is also referred to as a “precursor”, and the material IM after being cured is also referred to as a “film”.

Next, a method for manufacturing an article (a semiconductor device, a liquid crystal display device, a color filter, microelectromechanical systems (MEMS), or the like) using the planarization apparatus 100 is described. This manufacturing method includes a step of bringing a composition placed on a substrate (a wafer, a glass substrate, or the like) and a mold into contact with each other using the planarization apparatus 100, thereby planarizing the composition, a step of curing the composition, and a step of separating the composition and the mold from each other. This forms a planarization film on the substrate. Then, a process of forming a pattern on the substrate on which the planarization film is formed, using a lithography apparatus (patterning), or the like is performed, and the processed substrate is processed by another known processing step, thereby manufacturing an article. Examples of another known step include etching, resist removal, dicing, bonding, packaging, and the like. This manufacturing method can manufacture an article of a high quality as compared to conventional manufacturing methods.

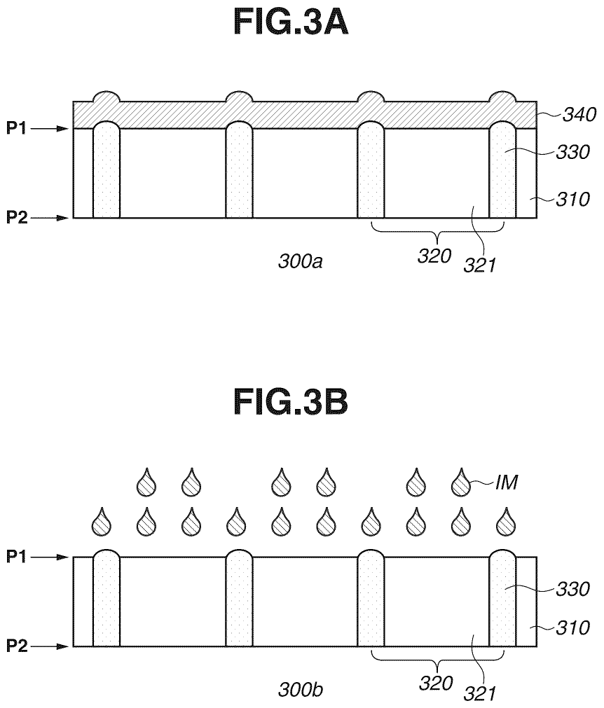

A description is given below of a case where a specific article is a semiconductor device as an example. For example, the semiconductor device is a photoelectric conversion sensor. FIGS. 3A and 3B are schematic diagrams illustrating a method for manufacturing a semiconductor device according to the present embodiment.

A semiconductor device 300a and a semiconductor device 300b each include a semiconductor substrate 310. The semiconductor substrate 310 includes pixels 320. Each pixel 320 includes a photoelectric conversion unit 321. The photoelectric conversion unit 321 generates a charge according to incident light. A signal based on the generated charge is output to a column circuit (not illustrated) from the pixel 320. The column circuit performs various processes such as an analog-to-digital (AD) conversion process for converting the input signal into a digital signal, a process of reducing a noise component, and the like. Then, the digital signals are sequentially read from the plurality of column circuits. Consequently, a semiconductor device according to the present embodiment can generate a signal based on a charge incident on the photoelectric conversion unit 321. A first surface P1 is an upper surface (a light incident surface) of the semiconductor substrate 310, and a second surface P2 is a lower surface of the semiconductor substrate 310 opposed to the first surface P1. For example, each of the semiconductor devices 300a and 300b is a back-side illumination semiconductor device including a plurality of wiring layers (not illustrated) on the second surface P2 side.

On the first surface P1, separation portions 330 formed by groove portions based on trenches are disposed, and the separation portions 330 separate a plurality of semiconductor regions. A photoelectric conversion unit 321 is disposed in each of the plurality of semiconductor regions, and adjacent photoelectric conversion units 321 are separated from each other by a separation portion 330 that extends from the first surface P1. For example, each separation portion 330 can be formed by embedding a member in a groove portion having a trench structure. For example, the member can be an insulator or a metal. If the separation portion 330 is formed by embedding a metal in the groove portion having the trench structure, light blocking performance improves. Further, the separation portion 330 may include a gap. The depth and the position of the separation portion 330 are not limited to the configuration in FIG. 3A. The separation portion 330 may be deep trench isolation (DTI) penetrating the semiconductor substrate 310, or may be DTI that does not penetrate the semiconductor substrate 310. The separation portion 330 may be configured to surround the entire periphery of the photoelectric conversion unit 321 in a planar view, or for example, may be configured only in opposite side portions of the photoelectric conversion unit 321.

FIG. 3A illustrates the state where an insulating film 340 is formed after the separation portion 330 is formed in the semiconductor substrate 310. The separation portion 330 has a convex structure. It can also be said that the convex structure is a structure where the uppermost portion of the member included in the separation portion 330 is higher than the first surface P1 with respect to the second surface P2. The insulating film 340 is formed by covering the separation portion 330. On an upper surface of the insulating film 340 located above the separation portion 330, a convex portion can be generated. If the flatness of the upper surface of the insulating film 340 is thus low, for example, there can be a case where a filter layer or a microlens disposed above the insulating film 340 cannot deliver desired performance. As the filter layer, various optical filters such as a color filter, an infrared cut filter, a monochrome filter, and the like can be used. As the color filter, a red, green, and blue (RGB) color filter in which red (R), green (G), and blue (B) pixels are provided, a red, green, blue, and white (RGBW) color filter in which a white (W) pixel is further provided, or the like can be used.

A configuration can be employed in which an insulating layer is provided instead of a color filter in the W pixel.

Accordingly, in the embodiment of the present disclosure, as illustrated in FIG. 3B, the precursor (the material IM) in the form of a liquid is applied by determining the amount of the material IM to be applied in advance so that a small amount of the material IM is applied to an upper portion of the separation portion 330, and a large amount of the material IM is applied to a portion other than the upper portion of the separation portion 330. Then, the flat surface 10 of the plate 9 is pressed against the liquid as needed, thereby curing the liquid.

An uncured material is applied to the upper portion of the separation portion 330 formed in advance, using an inkjet head on which a piezoelectric element as a discharge actuator is mounted. Specifically, this is achieved by implanting droplets N times (N is a natural number) per unit area in the upper portion of the separation portion 330 and implanting droplets N+1 or more times per unit area on the first surface P1. The number of droplets to be applied in this manner can be determined according to the formation pattern of the separation portion 330. Specifically, based on pattern data of a resist mask for the formation of the separation portion 330, droplets are applied while the relative positions between the discharge ports and the substrate 310 are changed according to a drawing map where the number (or the amount) of droplets to be applied onto the substrate 310 and the application positions in the upper surface are determined.

Since the regions between the plurality of separation portions 330 are thus embedded, the surface of a first film 350 to be subsequently formed is flat. As the liquid used in this case, a composition (a precursor of a cured film) that cures by receiving light energy is desirable.

For example, as an apparatus used to cure the composition, an exposure apparatus can be used. The exposure apparatus may be an ArF immersion exposure apparatus, an ArF dry exposure apparatus, or a KrF exposure apparatus. The amount of exposure of the exposure apparatus can also be adjusted according to the pattern of the separation portion 330.

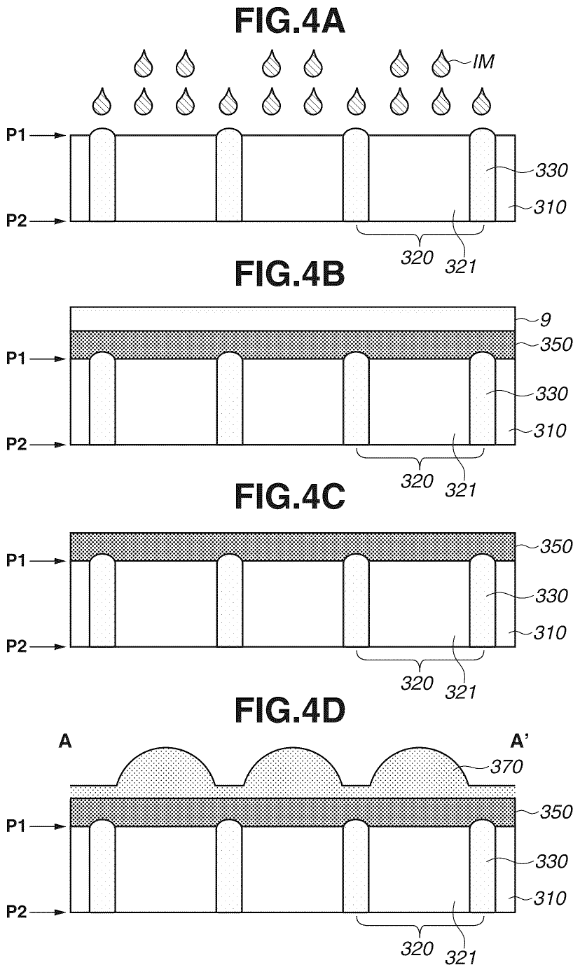

Next, a method for manufacturing a semiconductor device according to the present embodiment is described. FIGS. 4A, 4B, 4C, and 4D are schematic diagrams illustrating the method for manufacturing a semiconductor device according to the first embodiment. The manufacturing method illustrated in FIGS. 4A, 4B, 4C, and 4D is obtained by applying the planarization method described with reference to FIGS. 1, 2A, 2B, and 2C to the method for manufacturing a semiconductor device described with reference to FIG. 3B.

In FIG. 4A, similarly to FIG. 3B, after a step of preparing a semiconductor substrate 310 in which a separation portion 330 is formed, a material IM of a cured film is applied. The amount of application of the material IM is adjusted along the shape of an upper surface of the semiconductor substrate 310. The material IM is supplied so that the amount of the material IM applied to an upper portion of the separation portion 330 is smaller than the amount of the material IM applied to a flat upper surface of the semiconductor substrate 310 around the upper portion of the separation portion 330.

In this case, for example, it is possible to control the amount of the material IM to be applied by changing the number of droplets of the precursor (the liquid) of the material IM to be discharged using the inkjet method or by changing the size of each droplet.

Next, as illustrated in FIG. 4B, the plate 9 is brought into contact with the material IM as needed, thereby planarizing an upper surface of the material IM. Then, the material IM is irradiated with light through the plate 9. The material IM cures by being irradiated with light.

Next, as illustrated in FIG. 4C, the plate 9 is pulled away from the cured material IM on the semiconductor substrate 310. This planarization process forms a first film 350 including an upper surface having high flatness. For example, the material IM can be a precursor of an energy curable resin or a precursor of SOC.

Next, as illustrated in FIG. 4D, a microlens 370 is formed on the upper surface of the first film 350. The microlens 370 is formed on the first film 350 having high flatness and therefore is likely to deliver desired performance.

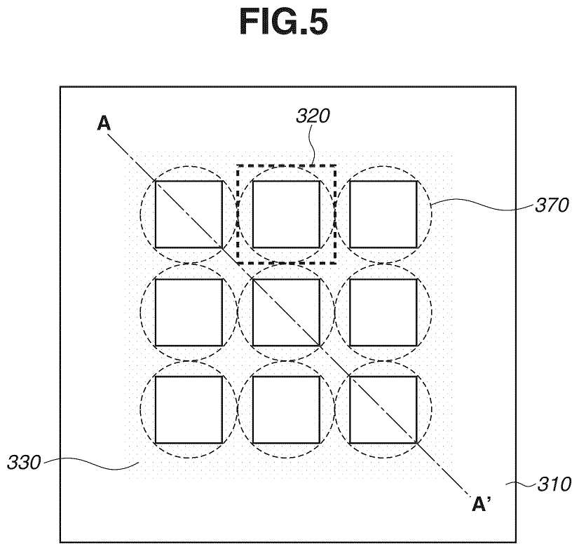

FIG. 5 illustrates the configuration of the semiconductor device according to the present embodiment in a planar view of the first surface P1. A cross-sectional view along a line AA′ illustrated in FIG. 5 corresponds to the configuration illustrated in FIG. 4D.

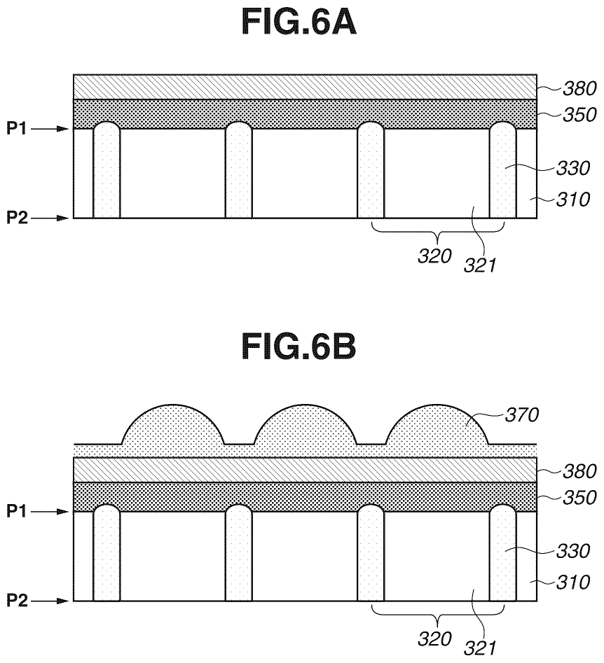

Before the step of forming the microlens 370 in FIG. 4D, a filter layer may be formed on the upper surface of the first film 350. FIGS. 6A and 6B illustrate steps of forming the filter layer. As illustrated in FIG. 6A, after FIG. 4C, a filter layer 380 is formed on the upper surface of the first film 350. Next, as illustrated in FIG. 6B, the microlens 370 is formed on an upper surface of the filter layer 380. The filter layer 380 is formed on the first film 350 having high flatness and therefore is likely to deliver desired performance.

As described above, based on the method for manufacturing a semiconductor device according to the present embodiment, it is possible to increase the flatness of an upper portion of a separation portion.

In the present embodiment, when the material IM is applied, the inkjet head is controlled so that fewer droplets are discharged onto the upper portion of the separation portion 330 than onto an upper portion of a portion other than the upper portion of the separation portion 330. The present disclosure, however, is not limited to this form. For example, when the material IM is applied, droplets are evenly applied to the separation portion 330 and a portion different from a portion where the separation portion 330 is provided. Then, the flat plate 9 is brought into contact with the material IM. This method can also make the amount of the material IM located in the upper portion of the separation portion 330 smaller than the amount of the material IM located in an upper portion of the portion different from the portion where the separation portion 330 is provided. Such a technique is also included in a step of applying a precursor so that the amount of the precursor applied to the upper portion of the separation portion 330 is smaller than the amount of the precursor applied to the portion other than the upper portion of the separation portion 330.

### Second Embodiment

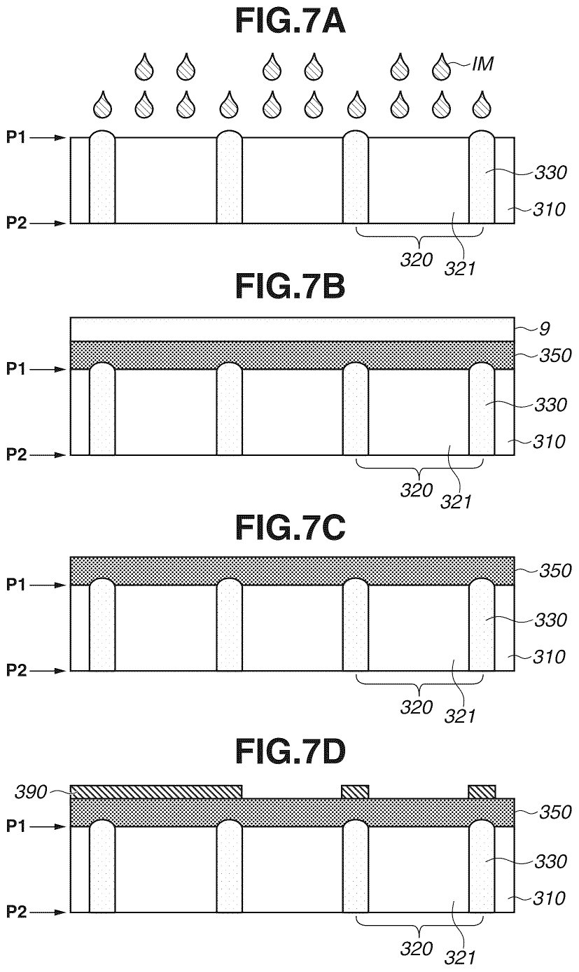

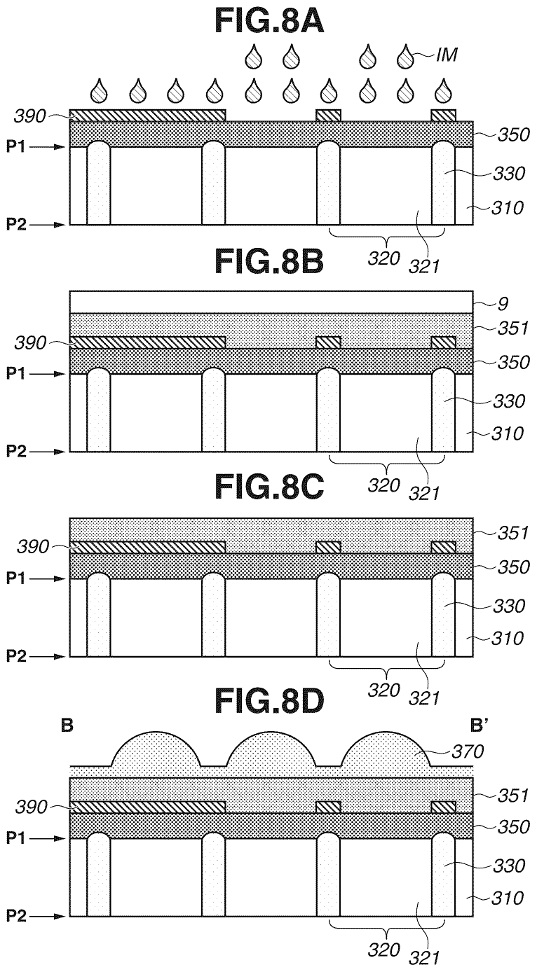

Methods for manufacturing a semiconductor device according to a second embodiment are described. FIGS. 7A, 7B, 7C, 7D, 8A, 8B, 8C, and 8D are schematic diagrams illustrating the methods for manufacturing a semiconductor device according to the second embodiment. The manufacturing methods illustrated in FIGS. 7A, 7B, 7C, 7D, 8A, 8B, 8C, and 8D are different from the manufacturing method described with reference to FIGS. 4A, 4B, 4C, and 4D in that a light-blocking portion 390 is formed on an upper portion of a part of the first film 350. Components and steps similar to those in the first embodiment are not described in detail below.

Steps illustrated in FIGS. 7A to 7C are similar to those in FIGS. 4A to 4C, and therefore are not described.

As illustrated in FIG. 7D, a light-blocking portion 390 is formed on the upper surface of the first film 350. For example, the light-blocking portion 390 can be formed of a metal. The light-blocking portion 390 is composed of a metal material having high light-blocking properties. For example, the light-blocking portion 390 can be composed of a single metal material of tungsten, aluminum, or the like. As the light-blocking portion 390, a laminated film of aluminum and a barrier metal (e.g., titanium, cobalt, nickel, or the like), a laminated film of tungsten and a barrier metal (e.g., titanium, cobalt, nickel, or the like), or the like can be used.

The manufacturing method illustrated in FIGS. 8A, 8B, 8C, and 8D is obtained by applying the planarization method described with reference to FIGS. 1, 2A, 2B, and 2C to steps after the light-blocking portion 390 is formed in FIG. 7D.

In FIG. 8A, after the step described with reference to FIG. 7D, a material IM of a cured film is applied. The amount of application of the material IM is adjusted along the shape of the upper surface of the first film 350. The material IM is supplied so that the amount of the material IM applied to an upper portion of the light-blocking portion 390 is smaller than the amount of the material IM applied to a flat upper surface of the first film 350 around the upper portion of the light-blocking portion 390. In this case, for example, it is possible to control the amount of the material IM to be applied by changing the number of droplets of the precursor (the liquid) of the material IM to be discharged using the inkjet method or by changing the size of each droplet. The material IM used in FIGS. 7A and 8A may be different, or may be the same.

Next, as illustrated in FIG. 8B, the plate 9 is brought into contact with the material IM as needed, thereby planarizing an upper surface of the material IM. Then, the material IM is irradiated with light through the plate 9. The material IM cures by being irradiated with light.

Next, as illustrated in FIG. 8C, the plate 9 is pulled away from the cured material IM on the first film 350. This planarization process forms a second film 351 including an upper surface having high flatness. For example, the material IM can be a precursor of an energy curable resin or a precursor of SOC.

Next, as illustrated in FIG. 8D, a microlens 370 is formed on the upper surface of the second film 351. The microlens 370 is formed on the second film 351 having high flatness and therefore is likely to deliver desired performance.

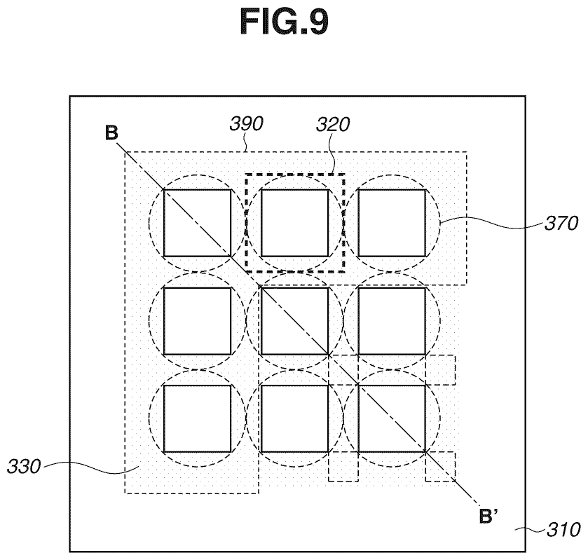

FIG. 9 illustrates the configuration of the semiconductor device according to the present embodiment in a planar view of the first surface P1. A cross-sectional view along a line BB′ illustrated in FIG. 9 corresponds to the configuration illustrated in FIG. 8D.

Before the step of forming the microlens 370 in FIG. 8D, a filter layer may be formed on the upper surface of the second film 351. The filter layer is formed on the upper surface of the second film 351 having high flatness and therefore is likely to deliver desired performance.

As described above, based on the method for manufacturing a semiconductor device according to the present embodiment, it is possible to increase the flatness of an upper portion of a separation portion. Further, it is possible to increase the flatness of an upper portion of a light-blocking portion.

In the present embodiment, when the material IM is applied, the inkjet head is controlled so that fewer droplets are discharged onto the upper portion of the light-blocking portion 390 than onto an upper portion of a portion other than the upper portion of the light-blocking portion 390. The present disclosure, however, is not limited to this form. For example, when the material IM is applied, droplets are evenly applied to the light-blocking portion 390 and a portion different from a portion where the light-blocking portion 390 is provided. Then, the flat plate 9 is brought into contact with the material IM. This method can also make the amount of the material IM located in the upper portion of the light-blocking portion 390 smaller than the amount of the material IM located in an upper portion of the portion different from the portion where the light-blocking portion 390 is provided. Such a technique is also included in a step of applying a precursor so that the amount of the precursor applied to the upper portion of the light-blocking portion 390 is smaller than the amount of the precursor applied to the portion other than the upper portion of the light-blocking portion 390.

### Third Embodiment

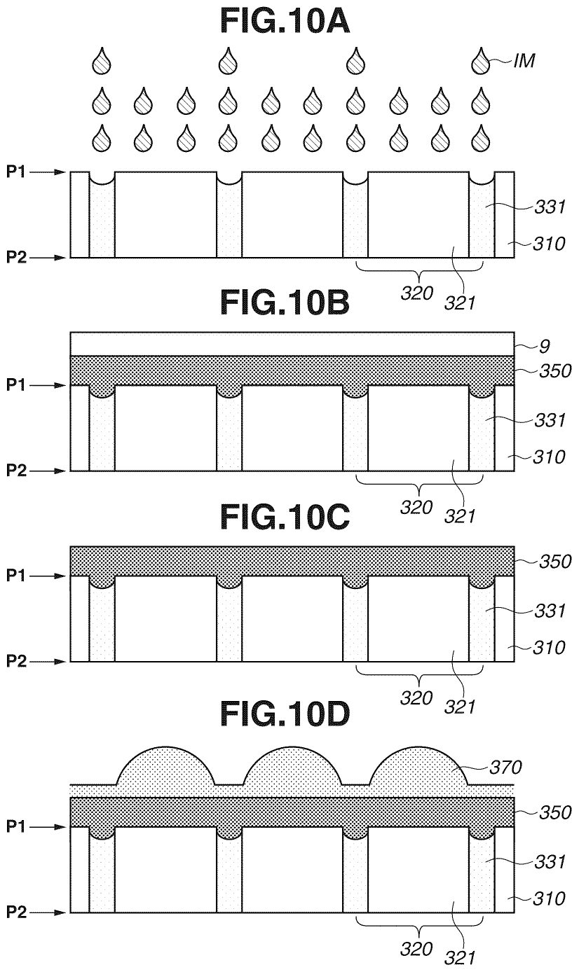

A method for manufacturing a semiconductor device according to a third embodiment is described. FIGS. 10A, 10B, 10C, and 10D are schematic diagrams illustrating the method for manufacturing a semiconductor device according to the third embodiment. The manufacturing method illustrated in FIGS. 10A, 10B, 10C, and 10D is different from the manufacturing method described with reference to FIGS. 4A, 4B, 4C, and 4D in the shape of a separation portion. Components and steps similar to those in the first and second embodiments are not described in detail below.

In FIG. 10A, after a step of preparing a semiconductor substrate 310 in which a separation portion 331 is formed, a material IM of a cured film is applied. The separation portion 330 according to the first embodiment has a convex structure relative to the first surface P1, whereas the separation portion 331 according to the present embodiment has a concave structure relative to the first surface P1. It can also be said that the concave structure is a structure where the uppermost portion of a member included in the separation portion 331 is lower than the first surface P1 with respect to the second surface P2. The amount of application of the material IM is adjusted along the shape of an upper surface of the semiconductor substrate 310. The material IM is supplied so that the amount of the material IM applied to an upper portion of the separation portion 331 is greater than the amount of the material IM applied to a flat upper surface of the semiconductor substrate 310 around the upper portion of the separation portion 331. In this case, for example, it is possible to control the amount of the material IM to be applied by changing the number of droplets of the precursor (the liquid) of the material IM to be discharged using the inkjet method or by changing the size of each droplet.

Next, as illustrated in FIG. 10B, the plate 9 is brought into contact with the material IM as needed, thereby planarizing an upper surface of the material IM. Then, the material IM is irradiated with light through the plate 9. The material IM cures by being irradiated with light.

Next, as illustrated in FIG. 10C, the plate 9 is pulled away from the cured material IM on the semiconductor substrate 310. This planarization process forms a first film 350 including an upper surface having high flatness. For example, the material IM can be a precursor of an energy curable resin or a precursor of SOC.

Next, as illustrated in FIG. 10D, a microlens 370 is formed on the upper surface of the first film 350. The microlens 370 is formed on the first film 350 having high flatness and therefore is likely to deliver desired performance.

Before the step of forming the microlens 370 in FIG. 10D, a filter layer may be formed on the upper surface of the first film 350. The filter layer is formed on the upper surface of the first film 350 having high flatness and therefore is likely to deliver desired performance.

As described above, based on the method for manufacturing a semiconductor device according to the present embodiment, it is possible to increase the flatness of an upper portion of a separation portion.

In the present embodiment, when the material IM is applied, the inkjet head is controlled so that more droplets are discharged onto the upper portion of the separation portion 331 than onto an upper portion of a portion other than the upper portion of the separation portion 331. The present disclosure, however, is not limited to this form. For example, when the material IM is applied, droplets are evenly applied to the separation portion 331 and a portion different from a portion where the separation portion 331 is provided. Then, the flat plate 9 is brought into contact with the material IM. This method can also make the amount of the material IM located in the upper portion of the separation portion 331 greater than the amount of the material IM located in an upper portion of the portion different from the portion where the separation portion 331 is provided. Such a technique is also included in a step of applying a precursor so that the amount of the precursor applied to the upper portion of the separation portion 331 is greater than the amount of the precursor applied to the portion other than the upper portion of the separation portion 331.

### Fourth Embodiment

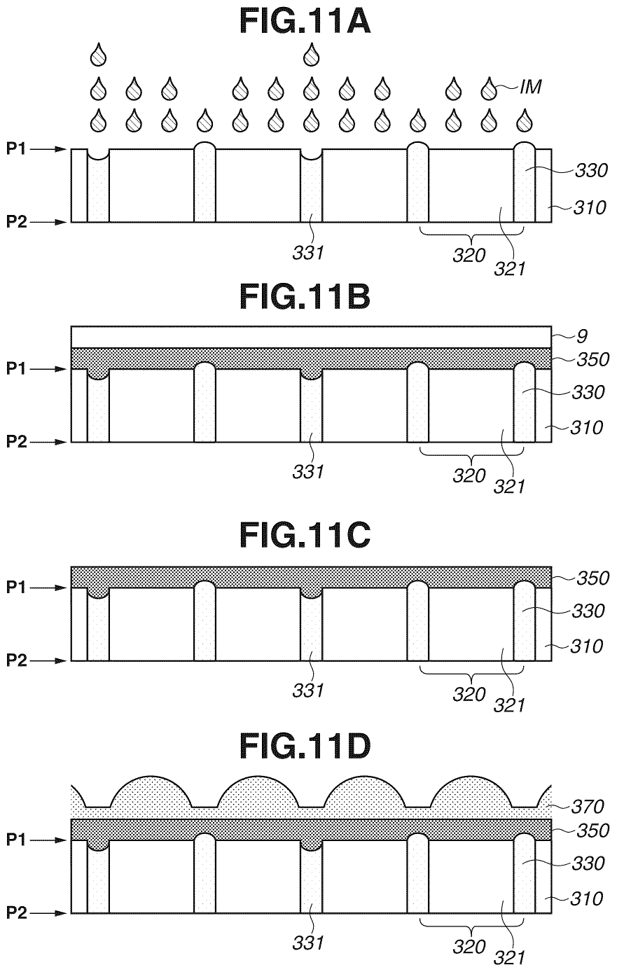

A method for manufacturing a semiconductor device according to a fourth embodiment is described. FIGS. 11A, 11B, 11C, and 11D are schematic diagrams illustrating the method for manufacturing a semiconductor device according to the fourth embodiment. The manufacturing method illustrated in FIGS. 11A, 11B, 11C, and 11D is different from the manufacturing methods described with reference to FIGS. 4A, 4B, 4C, and 4D and FIGS. 10A, 10B, 10C, and 10D in the shapes of separation portions. Components and steps similar to those in the first to third embodiments are not described in detail below.

In FIG. 11A, after the step of preparing a semiconductor substrate 310 in which a separation portion 330 and a separation portion 331 are formed, a material IM of a cured film is applied. The separation portion 330 has a convex structure (a first portion) relative to the first surface P1, whereas the separation portion 331 has a concave structure (a second portion) relative to the first surface P1. As described above, in the present embodiment, separation portions having different shapes are formed. The placement of the separation portions 330 and 331 is not limited to the configuration illustrated in FIGS. 11A, 11B, 11C, and 11D. For example, separation portions 330 and 331 may be alternately placed along the first surface P1, or a plurality of separation portions 330 may be placed adjacent to each other and a plurality of separation portions 331 may be placed adjacent to each other.

The amount of application of the material IM is adjusted along the shape of an upper surface of the semiconductor substrate 310. The material IM is supplied so that the amount of the material IM applied to an upper portion of the separation portion 330 is smaller than the amount of the material IM applied to a flat upper surface of the semiconductor substrate 310 around the upper portion of the separation portion 330. The material IM is supplied so that the amount of the material IM applied to an upper portion of the separation portion 331 is greater than the amount of the material IM applied to a flat upper surface of the semiconductor substrate 310 around the upper portion of the separation portion 331. In this case, for example, it is possible to control the amount of the material IM to be applied by changing the number of droplets of the precursor (the liquid) of the material IM to be discharged using the inkjet method or by changing the size of each droplet.

Next, as illustrated in FIG. 11B, the plate 9 is brought into contact with the material IM as needed, thereby planarizing an upper surface of the material IM. Then, the material IM is irradiated with light through the plate 9. The material IM cures by being irradiated with light.

Next, as illustrated in FIG. 11C, the plate 9 is pulled away from the cured material IM on the semiconductor substrate 310. This planarization process forms a first film 350 including an upper surface having high flatness. For example, the material IM can be a precursor of an energy curable resin or a precursor of SOC.

Next, as illustrated in FIG. 11D, a microlens 370 is formed on the upper surface of the first film 350. The microlens 370 is formed on the first film 350 having high flatness and therefore is likely to deliver desired performance.

Before the step of forming the microlens 370 in FIG. 11D, a filter layer may be formed on the upper surface of the first film 350. The filter layer is formed on the upper surface of the first film 350 having high flatness and therefore is likely to deliver desired performance.

As described above, based on the method for manufacturing a semiconductor device according to the present embodiment, it is possible to increase the flatness of an upper portion of a separation portion.

In the present embodiment, when the material IM is applied, the inkjet head is controlled so that fewer droplets are discharged to the upper portion of the separation portion 330 than to an upper portion of a portion other than the upper portion of the separation portion 330. The present disclosure, however, is not limited to this form. For example, when the material IM is applied, droplets are evenly applied to the separation portion 330 and a portion different from a portion where the separation portion 330 is provided. Then, the flat plate 9 is brought into contact with the material IM. This method can also make the amount of the material IM located in the upper portion of the separation portion 330 smaller than the amount of the material IM located in an upper portion of the portion different from the portion where the separation portion 330 is provided. Such a technique is also included in a step of applying a precursor so that the amount of the precursor applied to the upper portion of the separation portion 330 is smaller than the amount of the precursor applied to the portion other than the upper portion of the separation portion 330.

In the present embodiment, when the material IM is applied, the inkjet head is controlled so that more droplets are discharged onto the upper portion of the separation portion 331 than onto an upper portion of a portion other than the upper portion of the separation portion 331. The present disclosure, however, is not limited to this form. For example, when the material IM is applied, droplets are evenly applied to the separation portion 331 and a portion different from a portion where the separation portion 331 is provided. Then, the flat plate 9 is brought into contact with the material IM. This method can also make the amount of the material IM located in the upper portion of the separation portion 331 greater than the amount of the material IM located in an upper portion of the portion different from the portion where the separation portion 331 is provided. Such a technique is also included in a step of applying a precursor so that the amount of the precursor applied to the upper portion of the separation portion 331 is greater than the amount of the precursor applied to the portion other than the upper portion of the separation portion 331.

### Fifth Embodiment

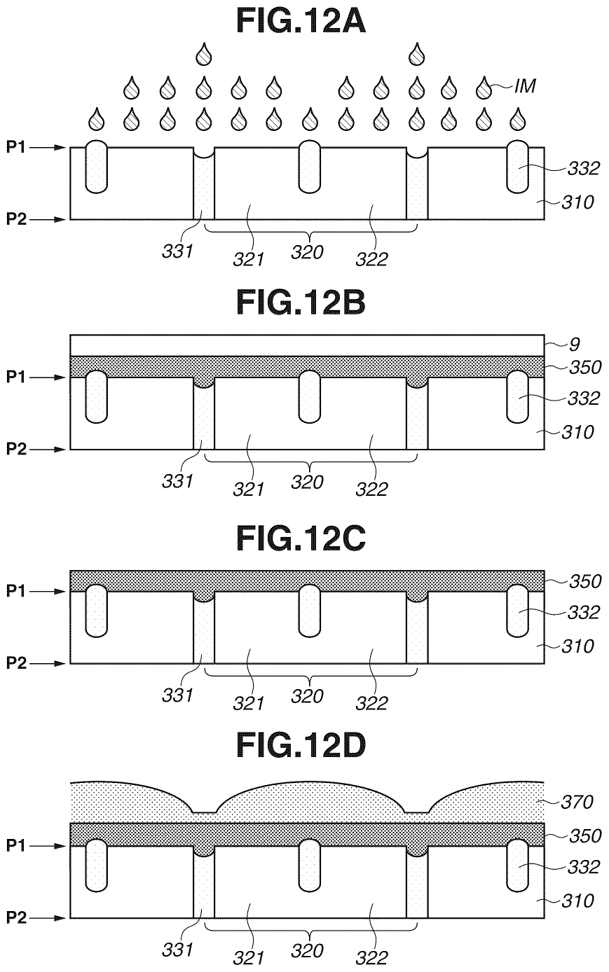

A method for manufacturing a semiconductor device according to a fifth embodiment is described. FIGS. 12A, 12B, 12C, and 12D are schematic diagrams illustrating the method for manufacturing a semiconductor device according to the fifth embodiment. The manufacturing method illustrated in FIGS. 12A, 12B, 12C, and 12D is different from the manufacturing method described with reference to FIGS. 11A, 11B, 11C, and 11D in the positional relationships between photoelectric conversion units and a microlens and the shapes of separation portions. Components and steps similar to those in the first to fourth embodiments are not described in detail below.

In FIG. 12A, after a step of preparing a semiconductor substrate 310 in which a separation portion 331 and a separation portion 332 are formed, a material IM of a cured film is applied. Pixels 320 each include a photoelectric conversion unit 321 and a photoelectric conversion unit 322. Each of the photoelectric conversion units 321 and 322 generates a charge according to incident light. Focus adjustment may be performed using a signal based on a charge incident on the photoelectric conversion unit 321 and a signal based on a charge incident on the photoelectric conversion unit 322. The Separation portions 331 and 332 are formed by groove portions based on trenches extending from the first surface P1. The distance between a bottom portion (a lower surface) of the separation portion 332 and the second surface P2 is greater than the distance between a bottom portion (a lower surface) of the separation portion 331 and the second surface P2. Photoelectric conversion units 321 and 322 included in a single pixel 320 are separated from each other by a separation portion 332, and photoelectric conversion units 321 and 322 included in different adjacent pixels 320 are separated from each other by a separation portion 331. The separation portion 331 has a concave structure (a second portion) relative to the first surface P1, whereas the separation portion 332 has a convex structure (a first portion) relative to the first surface P1.

The amount of application of the material IM is adjusted along the shape of an upper surface of the semiconductor substrate 310. The material IM is supplied so that the amount of the material IM applied to an upper portion of the separation portion 332 is smaller than the amount of the material IM applied to a flat upper surface of the semiconductor substrate 310 around the upper portion of the separation portion 332. The material IM is supplied so that the amount of the material IM applied to an upper portion of the separation portion 331 is greater than the amount of the material IM applied to a flat upper surface of the semiconductor substrate 310 around the upper portion of the separation portion 331. In this case, for example, it is possible to control the amount of the material IM to be applied by changing the number of droplets of the precursor (the liquid) of the material IM to be discharged using the inkjet method or by changing the size of each droplet.

Next, as illustrated in FIG. 12B, the plate 9 is brought into contact with the material IM as needed, thereby planarizing an upper surface of the material IM. Then, the material IM is irradiated with light through the plate 9. The material IM cures by being irradiated with light.

Next, as illustrated in FIG. 12C, the plate 9 is pulled away from the cured material IM on the semiconductor substrate 310. This planarization process forms a first film 350 including an upper surface having high flatness. For example, the material IM can be a precursor of an energy curable resin or a precursor of SOC.

Next, as illustrated in FIG. 12D, a microlens 370 is formed on the upper surface of the first film 350 by covering the photoelectric conversion units 321 and 322 separated from each other by the separation portion 332. The microlens 370 is formed on the first film 350 having high flatness and therefore is likely to deliver desired performance.

Before the step of forming the microlens 370 in FIG. 12D, a filter layer may be formed on the upper surface of the first film 350. At this time, it is desirable that the colors of the filter layer corresponding to the photoelectric conversion units 321 and 322 separated from each other by the separation portion 332 be the same. The filter layer is formed on the upper surface of the first film 350 having high flatness and therefore is likely to deliver desired performance.

As described above, based on the method for manufacturing a semiconductor device according to the present embodiment, it is possible to increase the flatness of an upper portion of a separation portion.

In the present embodiment, when the material IM is applied, the inkjet head is controlled so that fewer droplets are discharged onto the upper portion of the separation portion 332 than onto an upper portion of a portion other than the upper portion of the separation portion 332. The present disclosure, however, is not limited to this form. For example, when the material IM is applied, droplets are evenly applied to the separation portion 332 and a portion different from a portion where the separation portion 332 is provided. Then, the flat plate 9 is brought into contact with the material IM. This method can also make the amount of the material IM located in the upper portion of the separation portion 332 smaller than the amount of the material IM located in an upper portion of the portion different from the portion where the separation portion 332 is provided. Such a technique is also included in a step of applying a precursor so that the amount of the precursor applied to the upper portion of the separation portion 332 is smaller than the amount of the precursor applied to the portion other than the upper portion of the separation portion 332.

In the present embodiment, when the material IM is applied, the inkjet head is controlled so that more droplets are discharged onto the upper portion of the separation portion 331 than onto an upper portion of a portion other than the upper portion of the separation portion 331. The present disclosure, however, is not limited to this form. For example, when the material IM is applied, droplets are evenly applied to the separation portion 331 and a portion different from a portion where the separation portion 331 is provided. Then, the flat plate 9 is brought into contact with the material IM. This method can also make the amount of the material IM located in the upper portion of the separation portion 331 greater than the amount of the material IM located in an upper portion of the portion different from the portion where the separation portion 331 is provided. Such a technique is also included in a step of applying a precursor so that the amount of the precursor applied to the upper portion of the separation portion 331 is greater than the amount of the precursor applied to the portion other than the upper portion of the separation portion 331.

The shapes of the separation portions 331 and 332 are not limited to the configuration illustrated in FIGS. 12A, 12B, 12C, and 12D.

For example, the separation portion 331 may have a convex structure relative to the first surface P1 (a shape similar to that of the separation portion 330), or the separation portion 332 may have a concave structure relative to the first surface P1. In this case, the material IM is supplied so that the amount of the material IM applied to an upper portion of the separation portion 332 is greater than the amount of the material IM applied to a flat upper surface of the semiconductor substrate 310 around the upper portion of the separation portion 332. The material IM is supplied so that the amount of the material IM applied to an upper portion of the separation portion 331 is smaller than the amount of the material IM applied to a flat upper surface of the semiconductor substrate 310 around the upper portion of the separation portion 331.

### Sixth Embodiment

In a sixth embodiment, application examples are described where a semiconductor device manufactured by each of the manufacturing methods according to the first to fifth embodiments is used. For example, a semiconductor device 910 is a photoelectric conversion sensor.

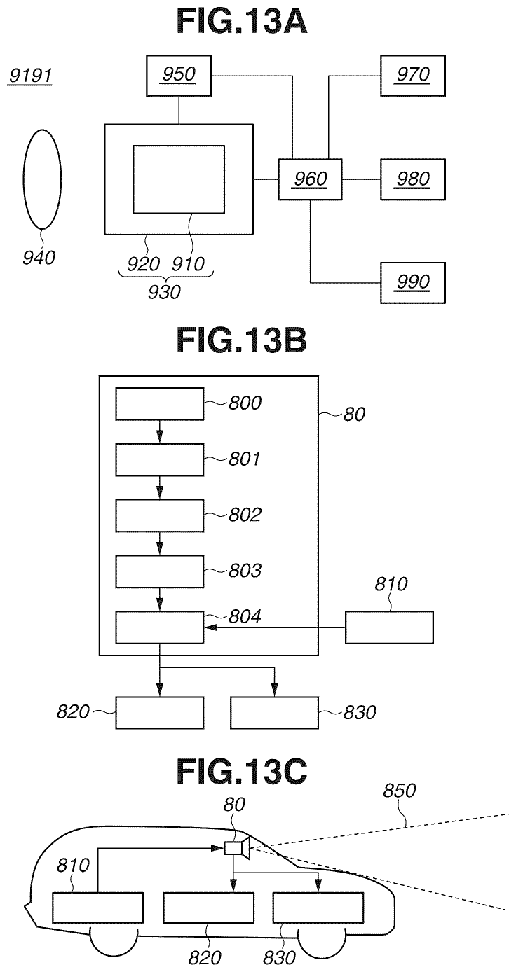

FIG. 13A is a schematic diagram illustrating a device 9191 as an application example. The device 9191 includes a semiconductor apparatus 930. The semiconductor apparatus 930 includes a semiconductor device 910 and a package 920 that accommodates the semiconductor device 910. The semiconductor device 910 can be manufactured by a manufacturing method according to another embodiment. The package 920 can include a base to which the semiconductor device 910 is fixed, and a cover body, such as glass or the like, opposed to the semiconductor device 910. The package 920 can further include a joint member, such as a bonding wire, a bump, or the like, connecting a terminal provided in the base and a terminal provided in the semiconductor device 910.

The device 9191 can include at least any of an optical apparatus 940, a control apparatus 950, a processing apparatus 960, a display apparatus 970, a storage apparatus 980, and a machine apparatus 990. The optical apparatus 940 is compatible with the semiconductor apparatus 930. For example, the optical apparatus 940 includes an optical system that guides light to the semiconductor apparatus 930, such as a lens, a shutter, and a mirror. The control apparatus 950 controls the semiconductor apparatus 930. The control apparatus 950 is a semiconductor apparatus such as an application-specific integrated circuit (ASIC).

The processing apparatus 960 processes a signal output from the semiconductor apparatus 930. The processing apparatus 960 is a semiconductor apparatus such as a CPU, an ASIC, or the like for configuring an analog front end (AFE) or a digital front end (DFE). The display apparatus 970 is an electroluminescent (EL) display apparatus or a liquid crystal display apparatus that displays information (an image) obtained by the semiconductor apparatus 930. The storage apparatus 980 is a magnetic device or a semiconductor device that stores information (an image) obtained by the semiconductor apparatus 930. The storage apparatus 980 is a volatile memory such as a static random-access memory (SRAM), a dynamic random-access memory (DRAM), or the like, or a non-volatile memory such as a flash memory, a hard disk drive, or the like.

The machine apparatus 990 includes a movable portion or a propulsive portion such as a motor, an engine, or the like. The device 9191 displays a signal output from the semiconductor apparatus 930 on the display apparatus 970, or transmits a signal output from the semiconductor apparatus 930 to outside using a communication apparatus (not illustrated) included in the device 9191. To this end, it is desirable that the device 9191 further include the storage apparatus 980 and the processing apparatus 960 separately from a storage circuit and an arithmetic circuit included in the semiconductor apparatus 930. The machine apparatus 990 may be controlled based on a signal output from the semiconductor apparatus 930.

The device 9191 is suitable for an electronic device such as an information terminal having an imaging function (e.g., a smartphone or a wearable terminal), a camera (e.g., an interchangeable lens camera, a compact camera, a video camera, or a monitoring camera), or the like. The machine apparatus 990 in the camera can drive the components of the optical apparatus 940 for a zooming operation, a focusing operation, and a shutter operation. Alternatively, the machine apparatus 990 in the camera can move the semiconductor apparatus 930 for an image stabilization operation.

The device 9191 can also be a transportation device such as a vehicle, a vessel, an aircraft, or the like. The machine apparatus 990 in the transportation device can be used as a moving device. The device 9191 as the transportation device is suitable for a transportation device that transports the semiconductor apparatus 930, or a transportation device that assists and/or automates driving (maneuvering) by an imaging function. The processing apparatus 960 for assisting and/or automating driving (maneuvering) can perform processing for operating the machine apparatus 990 as the moving device based on information obtained by the semiconductor apparatus 930. Alternatively, the device 9191 may be a medical device such as an endoscope or the like, a measurement device such as a distance measurement sensor or the like, an analysis device such as an electron microscope, an office device such as a copying machine or the like, or an industrial device such as a robot or the like.

According to the above embodiments, it is possible to obtain excellent pixel characteristics. Thus, it is possible to increase the value of a semiconductor apparatus. The increase in the value corresponds to at least any of the addition of a function, an improvement in the performance, improvements in the characteristics, an improvement in the reliability, an improvement in the manufacturing yield, a reduction in the environmental load, a reduction in the cost, a reduction in the size, and a reduction in the weight.

Thus, if the semiconductor apparatus 930 according to the present embodiment is used for the device 9191, it is also possible to improve the value of the device 9191. For example, when the semiconductor apparatus 930 is mounted on a transportation device, and an image outside the transportation device is captured, or the external environment is measured, it is possible to obtain excellent performance. Thus, in a case where a transportation device is manufactured and sold, the determination of the mounting of the semiconductor apparatus 930 according to the present embodiment on the transportation device is advantageous in enhancing the performance of the transportation device itself. Particularly, the semiconductor apparatus 930 is suitable for a transportation device that performs driving assistance and/or automatic driving of the transportation device using information obtained by a semiconductor apparatus.

Next, as another application example, a moving body is described. FIG. 13B illustrates an example of a photoelectric conversion system regarding an in-vehicle camera. A photoelectric conversion system 80 includes a semiconductor device 800. For example, the semiconductor device 800 is a photoelectric conversion device (an imaging device). The photoelectric conversion system 80 includes an image processing unit 801 that performs image processing on a plurality of pieces of image data acquired by the semiconductor device 800, and a parallax acquisition unit 802 that calculates a parallax (the phase difference between parallax images) from the plurality of pieces of image data acquired by the photoelectric conversion system 80. The photoelectric conversion system 80 may include an optical system (not illustrated) that guides light to the semiconductor device 800, such as a lens, a shutter, a mirror, and the like. In each of pixels included in the semiconductor device 800, a plurality of photoelectric conversion units almost conjugate to the pupil of the optical system may be disposed. For example, the plurality of photoelectric conversion units almost conjugate to the pupil may be disposed corresponding to a single microlens. The plurality of photoelectric conversion units may receive beams passing through positions different from each other in the pupil of the optical system, whereby the semiconductor device 800 may output pieces of image data corresponding to the beams passing through the different positions. Then, the parallax acquisition unit 802 may calculate a parallax using the output pieces of image data. The photoelectric conversion system 80 also includes a distance acquisition unit 803 that calculates the distance to a target object based on the calculated parallax, and a collision determination unit 804 that, based on the calculated distance, determines whether there is a possibility of a collision. The parallax acquisition unit 802 and the distance acquisition unit 803 are examples of a distance information acquisition unit that acquires distance information regarding the distance to a target object. That is, the distance information is information regarding the parallax, the amount of defocus, the distance to the target object, and the like. Using any of these pieces of distance information, the collision determination unit 804 may determine the possibility of a collision. The distance information may be acquired using time of flight (ToF). The distance information acquisition unit may be achieved by exclusively designed hardware, or may be achieved by a software module. Alternatively, the distance information acquisition unit may be achieved by a field-programmable gate array (FPGA), an ASIC, or the like, or may be achieved by the combination of these.

The photoelectric conversion system 80 is connected to a vehicle information acquisition apparatus 810 and can acquire vehicle information such as the speed of a vehicle, the yaw rate, the steering angle, and the like. The photoelectric conversion system 80 is also connected to an electronic control unit (ECU) 820 that is a control apparatus that outputs a control signal for producing a braking force in the vehicle based on the determination result of the collision determination unit 804. The photoelectric conversion system 80 is also connected to an alarm apparatus 830 that gives an alarm to a driver based on the determination result of the collision determination unit 804. For example, if there is a high possibility of a collision as the determination result of the collision determination unit 804, the ECU 820 controls the vehicle to avoid a collision and reduce damage by, for example, applying a brake, returning the gas pedal, or suppressing the engine output. The alarm apparatus 830 warns a user by, for example, setting off an alarm such as a sound or the like, displaying alarm information on a screen of an automotive navigation system or the like, or imparting a vibration to a seat belt or the steering.

In the present embodiment, the photoelectric conversion system 80 captures the periphery, such as the front direction or the rear direction, of the vehicle. FIG. 13C illustrates the photoelectric conversion system 80 in a case where the photoelectric conversion system 80 captures the front direction of the vehicle (an imaging range 850). The vehicle information acquisition apparatus 810 sends an instruction to the photoelectric conversion system 80 or the semiconductor device 800. With this configuration, it is possible to further improve the accuracy of distance measurement.

In the above description, an example has been described where a vehicle is controlled to avoid colliding with another vehicle. Alternatively, the present embodiment is also applicable to control for automatically driving a vehicle by following another vehicle, control for automatically driving a vehicle so as to stay in a lane, or the like. Further, the photoelectric conversion system 80 can be applied not only to a vehicle such as an automobile or the like but also to a moving body (a moving apparatus) such as a vessel, an aircraft, an industrial robot, or the like. The moving body includes one or both driving force generation unit that generates a driving force mainly used to move the moving body, and a rotating body mainly used to move the moving body. The driving force generation unit can be an engine, a motor, or the like. The rotating body can be a tire, a wheel, a screw of a vessel, a propeller, or the like. Additionally, the photoelectric conversion system 80 can be applied not only to a moving body but also to a device widely using object recognition, such as an intelligent transportation system (ITS) or the like.

The device according to the present embodiment can also be a transportation device such as a vehicle, a vessel, a flying object, or the like. A machine apparatus in the transportation device can be used as a moving device. The device as the transportation device is suitable for a transportation device that transports a semiconductor apparatus, or a transportation device that assists and/or automates driving (maneuvering) by an imaging function. A processing apparatus for assisting and/or automating driving (maneuvering) can perform processing for operating the machine apparatus as the moving device based on information obtained by the semiconductor apparatus.

Although in the present embodiment, a photoelectric conversion device has been described as an example of the semiconductor device, the semiconductor device may be another semiconductor device, or may be both a photoelectric conversion device and another semiconductor device.

According to the present disclosure, it is possible to increase the flatness of an upper portion of a separation portion included in a semiconductor device.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-230270, filed Dec. 26, 2024, which is hereby incorporated by reference herein in its entirety.

What is claimed is:

1. A method for manufacturing a semiconductor device including a substrate, the substrate including a first surface, a second surface opposed to the first surface, and a plurality of semiconductor regions disposed between the first and second surfaces, the method comprising:
preparing the substrate to include a separation portion having a trench structure extending from the first surface and a member disposed inside the trench structure, the separation portion separating the plurality of semiconductor regions; and
forming a first film including a flat upper surface by applying a precursor onto the substrate so that an amount of the precursor applied to an upper portion of the separation portion is different from an amount of the precursor applied to a portion other than the upper portion of the separation portion.

2. The method for manufacturing the semiconductor device according to claim 1, wherein the separation portion has a convex structure relative to the first surface, and, in the forming of the first film, the precursor is applied onto the substrate so that the amount of the precursor applied to the upper portion of the separation portion is smaller than the amount of the precursor applied to the portion other than the upper portion of the separation portion.

3. The method for manufacturing the semiconductor device according to claim 1, wherein the separation portion has a concave structure relative to the first surface, and, in the forming of the first film, the precursor is applied onto the substrate so that the amount of the precursor applied to the upper portion of the separation portion is greater than the amount of the precursor applied to the portion other than the upper portion of the separation portion.

4. The method for manufacturing the semiconductor device according to claim 1, wherein, in the forming of the first film, an upper surface of the precursor is planarized and cured so that the first film includes the flat upper surface.

5. The method for manufacturing the semiconductor device according to claim 1, wherein, in the forming of the first film, a superstrate is brought into contact with the precursor.

6. The method for manufacturing the semiconductor device according to claim 5, wherein, in the forming of the first film, the precursor is cured in a state where the superstrate is in contact with the precursor.

7. The method for manufacturing the semiconductor device according to claim 1,
wherein the substrate includes a photoelectric conversion unit configured to generate charge according to light incident on the first surface, and
wherein, in a planar view of the first surface, the photoelectric conversion unit is disposed between a part of the separation portion and another part of the separation portion.

8. The method for manufacturing the semiconductor device according to claim 7, wherein, in the forming of the first film, the precursor is applied so that an amount of the precursor applied to an upper portion of the photoelectric conversion unit is different from the amount of the precursor applied to the upper portion of the separation portion.

9. The method for manufacturing the semiconductor device according to claim 7, wherein, in the forming of the first film, the separation portion has a convex structure relative to the first surface, and the precursor is applied so that an amount of the precursor applied to an upper portion of the photoelectric conversion unit is greater than the amount of the precursor applied to the upper portion of the separation portion.

10. The method for manufacturing the semiconductor device according to claim 7, wherein, in the forming of the first film, the separation portion has a concave structure relative to the first surface, and the precursor is applied so that an amount of the precursor applied to an upper portion of the photoelectric conversion unit is smaller than the amount of the precursor applied to the upper portion of the separation portion.

11. The method for manufacturing the semiconductor device according to claim 1, further comprising:
forming a light-blocking portion at a position, on a part of the first film, overlapping the separation portion; and
forming a second film including a flat upper surface by applying a precursor onto the first film so that an amount of the precursor applied to an upper portion of the light-blocking portion is smaller than the amount of the precursor applied to a portion other than the upper portion of the light-blocking portion.

12. The method for manufacturing the semiconductor device according to claim 1,
wherein the separation portion includes a first portion having a convex structure relative to the first surface and a second portion having a concave structure relative to the first surface, and
wherein, in the forming of the first film, the precursor is applied so that an amount of the precursor applied to an upper portion of the first portion is smaller than the amount of the precursor applied to an upper portion of the second portion.

13. The method for manufacturing the semiconductor device according to claim 12, wherein a distance between a bottom portion of the first portion and the second surface is greater than a distance between a bottom portion of the second portion and the second surface.

14. The method for manufacturing the semiconductor device according to claim 13, further comprising forming a microlens on the first film,
wherein, in the forming of the microlens, a single microlens is formed so that the plurality of semiconductor regions to be separated from each other by the first portion is covered.

15. The method for manufacturing the semiconductor device according to claim 1, wherein, in the forming of the first film, the first film is formed of a material different from a material of the separation portion.

16. The method for manufacturing the semiconductor device according to claim 1, wherein the semiconductor device includes a plurality of wiring layers, and the second surface is disposed between the first surface and the plurality of wiring layers.

17. The method for manufacturing the semiconductor device according to claim 1, further comprising forming a microlens on the first film.

18. The method for manufacturing the semiconductor device according to claim 1, further comprising forming a filter layer on the first film.

19. The method for manufacturing a semiconductor device according to claim 1, further comprising:
forming a filter layer on the first film; and
forming a microlens on the filter layer.
